(19) United States
(12) Patent Application Publication
(10) Pub. No.: US 2018/0066663 A1
(43) Pub. Date: Mar. 8, 2018

(54) COOLING USING COOLANT-DRIVEN FANS

(71) Applicant: Intel Corporation, Santa Clara, CA (US)

(72) Inventors: Devdatta P. Kulkarni, Olympia, WA (US); Robin A. Steinbrecher, Olympia, WA (US)

(21) Appl. No.: 15/260,121

(22) Filed: Sep. 8, 2016

(51) Int. Cl. F04D 25/04; H05K 7/20

(52) U.S. Cl. CPC F04D 25/045; H05K 7/20327

(57) ABSTRACT

Processes, apparatuses, and systems are associated with using coolant-driven fans to cool computer systems. In embodiments, the flow of coolant through tubes used to cool cold plates within the system may be used to drive one or more fans within the system to provide additional airflow to cool components, for example, components to be air cooled that are attached to a motherboard. Other embodiments may be described and/or claimed.

### FIELD

Embodiments of the present disclosure generally relate to the field of computing systems. More specifically, embodiments of the present disclosure relate to cooling electronic components in a computing system.

### BACKGROUND

As electronic components decrease in size and increase in power requirements, cooling individual components as well as collections of components will become increasingly important to ensure proper computing system function moving forward. For example, the size of central processing unit (CPU) dies are miniaturizing at the same time the number of cores, heat dissipation, and thermal design power (TDP) of these dies are increasing. This can result in a higher heat flux from the CPU dies and increase the challenge for thermally managing the CPU. Legacy cooling solutions seek to achieve operational performance goals with new components, and system architects seek to lower junction die temperatures in product segments such as desktops, workstations or servers.

Legacy air cooled reference platforms are typically built per American Society of Heating, Refrigerating and Air-Conditioning Engineers (ASHRAE) Class A2. In legacy implementations to support high-power dense solutions, liquid-enhanced cooling solutions are typically used where components are cooled by liquid cold plates, and heat is dissipated to the outside air via heat exchangers (HEX) located inside or outside the computer chassis. Some of these heat exchangers may be implemented as cooling distribution units (CDU).

In many liquid-cooled servers, all the components are cooled by using monolithic or discrete cold plates to capture heat. To capture heat and remove it, gap filler thermal interface material in thermal contact with a cold plate and one or more heat-generating components may be used. In addition, there may be very small components on a motherboard (MB) that generate heat, as well as the MB generating heat due to Joule heating that needs dissipating that may not be accessible by a cold plate. To cool these components, air moves around the MB or other components to dissipate the rest of the heat.

These air cooling techniques may rely on one of two designs. First, electrically powered fans proximate to the components may move cooling air around the components to dissipate heat. However, these electric fan motors use electricity and generate heat themselves, and therefore may add heat to the overall system. Second, systems and component layout may be designed without fans to attempt to cause natural convection airflow patterns to dissipate heat to the cooler air outside the system. However, convection air patterns may not be reliable. Furthermore, the technique requires expensive design and requires a lengthy test time to make sure cooling is effective.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 is a diagram of a coolant-driven fan system for cooling, in accordance with various embodiments.

FIG. 2 is a diagram of a coolant-driven fan for cooling, in accordance with various embodiments.

FIG. 3 illustrates an example of an implementation of a liquid coolant-driven fan system for cooling, in accordance with various embodiments.

FIG. 4 illustrates an example of an implementation of a liquid enhanced air cooling (LEAC) coolant-driven fan system for cooling, in accordance with various embodiments.

FIG. 5 illustrates a block diagram of a process for implementing a tunable pumped two-phase liquid cooling thermal management system, in accordance with various embodiments.

### DETAILED DESCRIPTION

In embodiments, cooling using coolant-driven fans may address the deficiencies stated above, and more. In embodiments, the flow of coolant through tubes used to cool cold plates within the system may be used to drive one or more fans within the system to provide airflow to cool components, for example, components on a motherboard. In embodiments, coolant-driven fans may result in reduced energy consumption and reduced cost in comparison to a pure liquid cooled platform and hybrid-cooled platform. In addition, the reliability of the overall cooling solution may increase with no electrical parts to control air movement. In embodiments, the heat load transfer to the air may be reduced for an entire data center and may lead to reduced capital equipment costs. In embodiments, the coolant in the cooling system may be in a liquid state, a vapor state, or both.

In embodiments, the airflow at the server board level may be generated by one or more fans driven by coolant flow passing through tubes. One objective may be to simplify the complex, machined cold plates and remove residual heat from less critical components through airflow without adding additional electric components.

Processes, apparatuses, and systems associated with cooling using coolant fans are disclosed herein. In embodiments, a cooling apparatus may include one or more fan blades, a tube to carry coolant flowing within the tube, the tube proximate to the one or more fan blades, and a mechanism within the tube, the mechanism kinetically coupled to the one or more fan blades, where the flow of the coolant is to cause the mechanism to move the one or more fan blades to create airflow. In other embodiments, the mechanism may include a plurality of vanes rotatable around an axis, where the vanes are to rotate around the axis when the coolant flows within the tube, and at least one of the plurality of vanes is magnetically coupled to the one or more fan blades to cause the one or more fan blades to move when the coolant flows through the tube. In other embodiments, the tube may be made of a material that allows magnetic flux lines to pass through the material.

Embodiments implemented related to one or more servers may provide original equipment manufacturing (OEM), original design manufacturing (ODM) and end users with energy savings and/or increased heat capture ratios at the server level. This in turn may help decrease the power usage efficiency (PUE) ratio for data center applications.

In the following description, various aspects of the illustrative implementations are described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “including,” “having,” and the like, as used with respect to embodiments of the present disclosure, are synonymous.

The terms “coupled with” and “coupled to” and the like may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. By way of example and not limitation, “coupled” may mean two or more elements or devices are coupled by electrical connections on a printed circuit board such as a motherboard, for example. By way of example and not limitation, “coupled” may mean two or more elements/devices cooperate and/or interact through one or more network linkages such as wired and/or wireless networks. By way of example and not limitation, a computing apparatus may include two or more computing devices “coupled” on a motherboard or by one or more network linkages.

Various embodiments are disclosed that include using cooling by cooling-driven fans to moderate or cool temperatures of electronic components such as those on a motherboard.

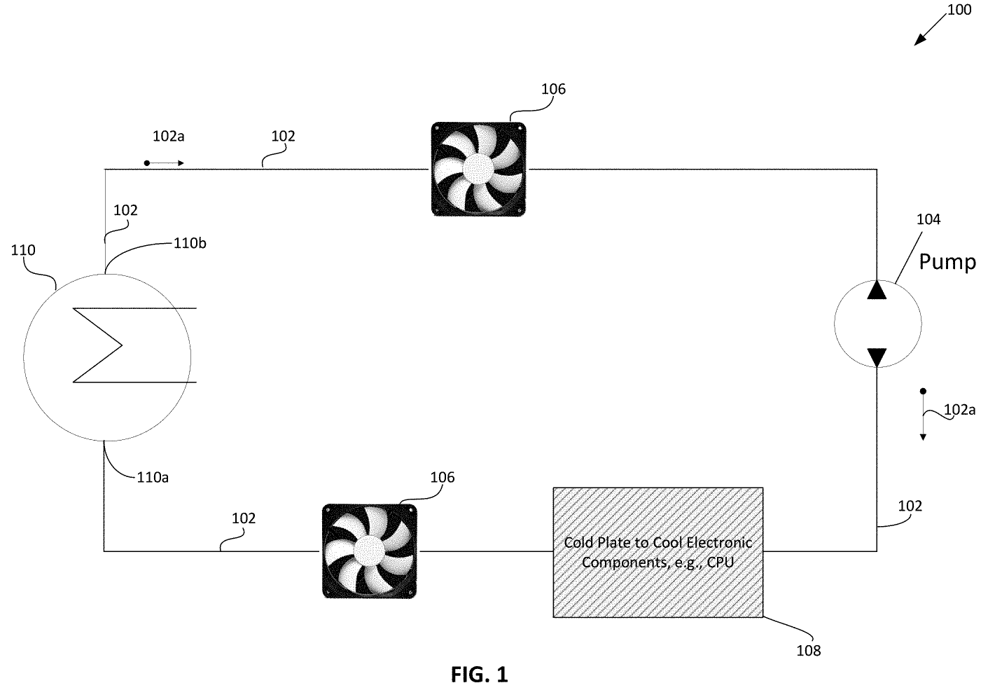

FIG. 1 is a diagram of a coolant-driven fan system for cooling, in accordance with some embodiments. Diagram 100 shows a schematic of two coolant-driven fans 106 that are driven by coolant flowing within coolant tube 102, where the coolant is moving in a direction 102a. In embodiments, the coolant tube 102 includes a mechanism to cause blades of fans 106 to rotate and generate airflow, when coolant flows through tube 102. In embodiments, diagram 100 may represent a schematic of a cooling system cooling a computer server or some similar heat-generating electronic device, such as a circuit board, and/or components that may be attached to it. In embodiments, the coolant tube 102 may be a sealed tube caring coolant to move thermal energy from one location to another. The coolant tube 102 may be connected to a pump 104 that may pump the coolant in the direction 102a. In embodiments, the coolant may be in a fluid state, a vapor state, or a combination of fluid and vapor states.

The coolant tube 102 may be connected to a cold plate 108 that may be to dissipate heat from the cold plate 108 to the coolant flowing in coolant tube 102. In embodiments, the cold plate 108 may be directly thermally coupled to a device such as a central processing unit (CPU) (not shown), or thermally coupled via a thermal gap filler material (not shown). After leaving the cold plate 108, the coolant in coolant tube 102 may flow to a heat exchanger 110 at heat exchanger input 110a, where heat may be dissipated from the coolant. When the coolant exits the heat exchanger at output 110b, the coolant may be cooler and able to readily absorb additional thermal energy. In embodiments, the pump 104 and the heat exchanger 110 may be powered by the same electrical power source, such as a server power supply (not shown).

In embodiments, the direction and force of flow 102a of the coolant in the coolant tube 102 may be determined by pump 104. In embodiments where the coolant is a two-phase coolant, the force of flow of the coolant in coolant tube 102 may also be impacted by heating of the coolant, for example, by coming into contact with cold plate 108, so that a two-phase coolant may change state from a liquid state to at least a partial vapor state. In embodiments, except for the mechanism included in tube 102 to cause blades of fans 106 to rotate and generate airflow, the cooling system including pump 104, cold plate 108 and heat exchanger 110 may be the cooling system of U.S. patent application Ser. No. 15/140,014, filed Apr. 27, 2016, and entitled “TUNABLE TWO-PHASE LIQUID COOLING THERMAL MANAGEMENT METHOD AND APPARATUS.” The mechanism included in tube 102 to cause blades of fans 106 to rotate and generate airflow, and other related aspects, will be further described with references to the remaining drawings.

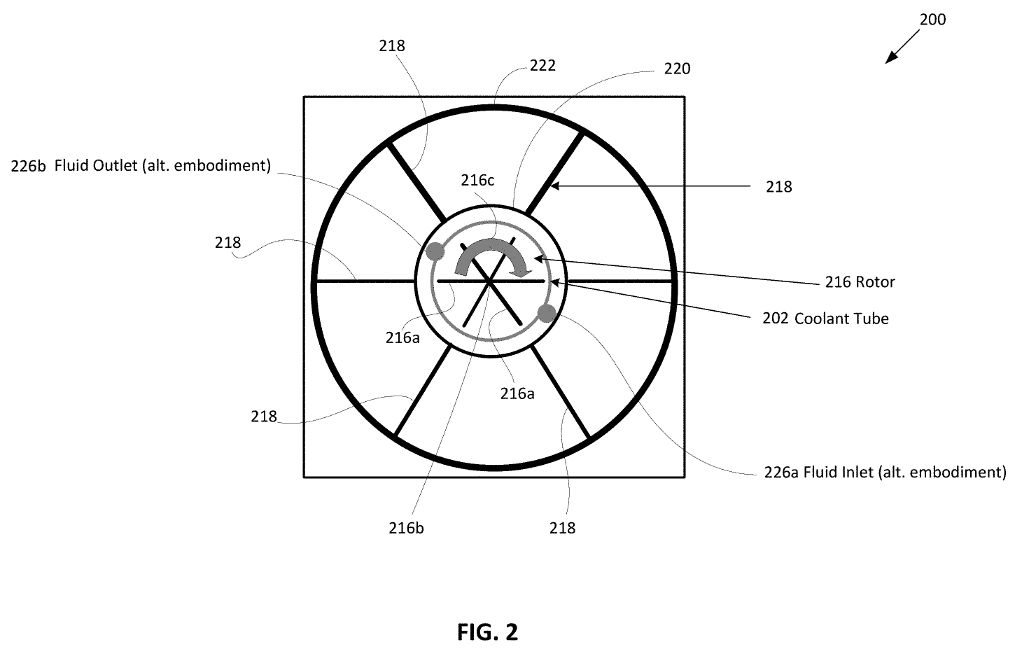

FIG. 2 is a diagram of a coolant-driven fan for cooling, in accordance with some embodiments. Diagram 200 represents an embodiment of a cross-section of the coolant fan 106 of FIG. 1.

In embodiments, the cooling fan 200 , which may be similar to cooling fan 106 of FIG. 1, may include a plurality of fan blades 218 that are attached to a collar 220 that may rotate around the coolant tube 202. In embodiments, coolant tube 202 may be similar to coolant tube 102 of FIG. 1. Rotor 216 may be inside coolant tube 202, and may include a plurality of vanes 216a attached to a hub 216b, about which the plurality of vanes 216a may rotate in the direction 216c. In embodiments, the rotor 216 may be kinetically coupled to the fan blades 218 to cause the fan blades 218 to turn as the rotor 216 turns.

In embodiments, coolant flowing in the coolant tube 202 (perpendicular to the plane of diagram 200), may come into contact with individual vanes 216a to cause them to rotate about the rotor hub 216c. In embodiments, the vanes 216a may be made of a permanent magnetic material. The vanes 216a may be made of any shape, such as a screw shape or helical shape, that may allow cooling fluid to axially pass through the coolant tube 202 and rotate the vanes 216b around the hub 216c, spinning rotor 216 and thus rotating the fan blades 218. In embodiments, the coolant tube 202 may be made of material that allows magnetic flux lines to pass through it. Examples of suitable material may include aluminum or stainless steel.

In other embodiments, the coolant tube 202 may act as a chamber with coolant entering the chamber at inlet 226a and exiting the chamber at outlet 226b. As the coolant passes from the inlet 226a to the outlet 226b, vanes 216a may rotate around the hub 216b causing a rotation 216c of the rotor 216.

In embodiments, vanes 216a may be shaped in a variety of ways to facilitate rotation based upon coolant encountering the vanes 216a as the coolant travels along coolant tube 102. In embodiments, rotation of the vanes 216a around the hub 216b may cause the fan blades 218 to rotate by being kinetically coupled to the vanes 216a. For example, the fan blades 218 may be made of iron or some other magnetic material so that a magnetic coupling occurs between the fan blades 218 and the rotating vanes 216a. In other embodiments, there may be intermediate mechanisms (not shown) to provide a kinetic coupling so that the ratio of revolutions of the vanes 216a about their axis (hub 216b) and revolutions of the fan blades 218 is other than 1:1. In embodiments, an outer ring 222 may be used to stabilize and/or support individual fan blades 218.

In embodiments, the coolant may be a single-phase coolant in a liquid state or a two-phase coolant that may be in a liquid state, vapor state, or both.

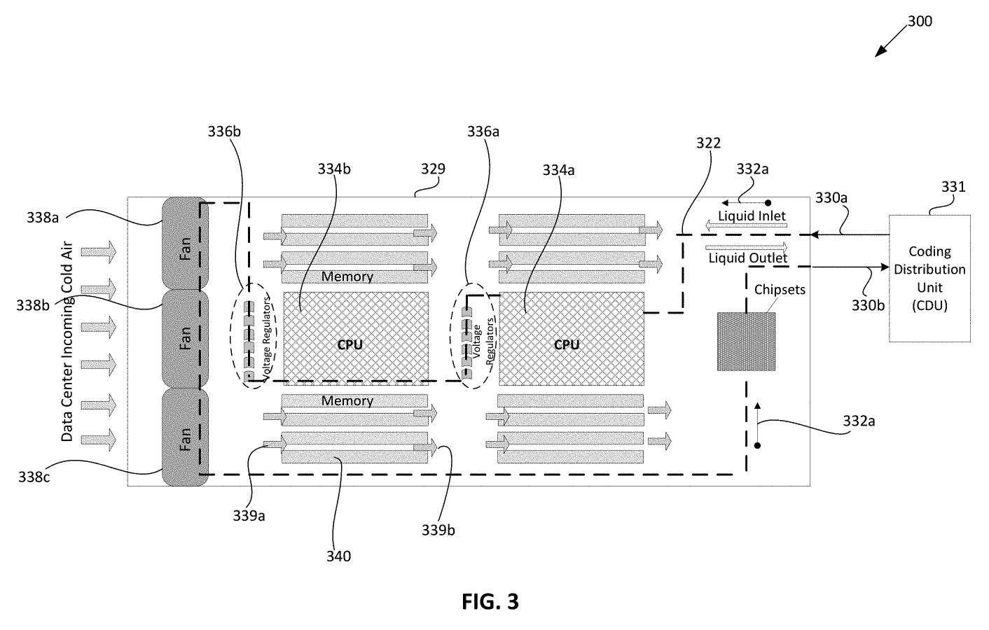

FIG. 3 illustrates an example of an implementation of a liquid coolant-driven fan system for cooling, in accordance with some embodiments. Diagram 300 shows an implementation of a server board 329 that is being cooled by liquid coolant from a cooling distribution unit (CDU) 331. The liquid coolant, which may be a single-phase liquid coolant, may be a fluid such as water or a glycol-water mixture.

In embodiments, the CDU 331 may provide cooled liquid coolant through line 330a, which may flow into coolant tube 322 on server board 329. The warmed liquid coolant may return to the CDU 331 from the server board 329 via line 330b. In embodiments, the direction of the coolant flow and the pressure of the coolant may be maintained through a pump (not shown) within the CDU 331.

The coolant may flow from the CDU 331 via coolant line 330a into coolant tube 322 flowing in direction 332a, to a cold plate (not shown) thermally connected to a first CPU 334a to dissipate heat from the first CPU 334a. In embodiments, the cold plate (not shown) may be a metal plate underneath the CPU 334a through which coolant from coolant tube 322 may circulate to transfer heat from the cold plate to the coolant. In embodiments, the cold plate may be directly connected to the first CPU 334a or connected via a thermal gap filler (not shown). The coolant may then continue to flow through coolant tube 322 to a first set of voltage regulators 336a. In embodiments, the coolant tube 322 may thermally couple with the voltage regulators 336a by directly contacting the regulators or by coming into contact with a thermal gap material that contacts the regulators. In embodiments, the first CPU 334a and the first set of voltage regulators 336a may instead be any component attached to server board 329. In embodiments, the coolant flowing through coolant tube 322 may then go to a second CPU 334b, and a second set of voltage regulators 336b. In embodiments, the components on server board 329 may be thermally coupled to the coolant flowing within coolant tube 322 to a cold plate or other cold sink using heat pipes or a solid construction path.

The liquid coolant in coolant tube 322 may then flow to one or more fans 338a-338c, where the flow of the liquid coolant may operate to cause the blades of the fans (not shown) to rotate and therefore draw cool ambient air from outside of the server over the components that may be attached to the server board 329. For example, memory 340 may be attached to the server board 329, and during operation the memory 340 may generate heat to be dissipated that is not dissipated by the cold plate. In embodiments, cool air 339a, moved by fans 338a-338c, may flow into and over the memory 340 and exit as warmed air 339b. The air may continue to flow until it exits the server board 329.

In embodiments, fans 338a-338c may be powered by a single-phase liquid coolant pumped by the CDU 331. In embodiments, this may include a rotor 216 with vanes 216a located within the tube 202 which can then rotate fan blades 218 outside via magnetic coupling, similar to the fan operation described in diagram 200 of FIG. 2. These rotating fan blades 218 may then generate airflow to cool miscellaneous components on the motherboard. In embodiments, the energy required to rotate these fans may be provided by fluid flowing through tubes and may not consume any electrical energy from the server power supply (not shown). In embodiments, the rotor 216 may be designed for a minimal pressure drop for the liquid coolant as the liquid coolant flows through the rotor 216 to rotate the vanes 216a around the hub 216b. Therefore, the fan operation may not impact the CDU 331 dramatically.

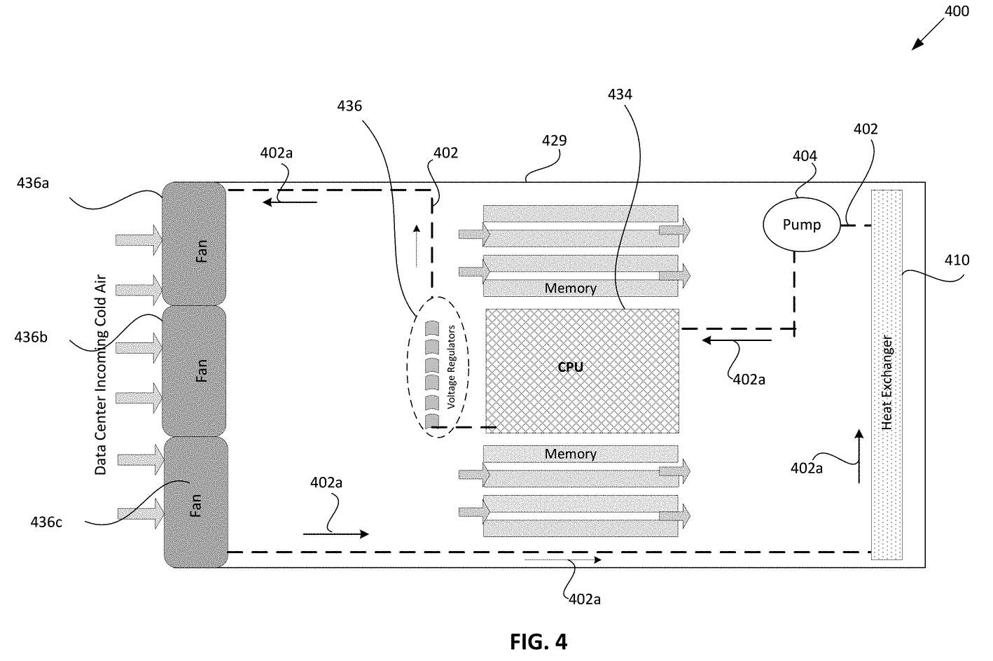

FIG. 4 illustrates an example of an implementation of a liquid enhanced air cooling (LEAC) coolant-driven fan system for cooling, in accordance with some embodiments. Diagram 400 shows an implementation of a server board 429 that is being cooled by a two-phase liquid coolant. In embodiments a two-phase liquid coolant may include R134a™, Novec 7000™, or other engineering fluids having a low boiling point. It should be appreciated that a single-phase coolant may also be used in these embodiments.

In embodiments, the two-phase coolant may flow in direction 402a a through a heat exchanger 410, which may be similar to the heat exchanger 110 of FIG. 1. The two-phase coolant, which at this stage may be liquid, may exit the heat exchanger 410 and, via coolant tube 402, which may be similar to coolant tube 102 of FIG. 1, flow to pump 404, which may be similar to pump 104 of FIG. 1. The two-phase coolant may then flow to the CPU 434. In embodiments, the fluid may enter a cold plate (not shown) below and coupled to the CPU 434, and extract heat from the CPU 434, warming the two-phase coolant. The pumped two-phase coolant may also be thermally coupled to voltage regulators 436 or other components (not shown).

In embodiments, as the two-phase coolant may be heated, the coolant may be converted to a liquid/gas coolant mixture (two phase). The liquid/gas coolant mixture may flow in direction 402a to fans 436a-436c, which may be similar to the fan shown and described in diagram 200 in FIG. 2. The liquid/gas coolant mixture flows through the fans 436a-436c, and in particular through the rotor 216 as shown in FIG. 2, to cause the blades 218 to turn. Because of the conversion from liquid to vapor, due to density differences, the rotor 216 becomes more efficient and behaves as an expansion valve, similar to one in a refrigerator unit. This may help to reduce the temperature of the mixture passing through the rotor 216. As a result, improved thermal performance of the coolant may be achieved by using a two-phase coolant loop using the added orifice that is part of fans 436a-436c and create efficient airflow by causing the fans 436a-436c to operate, when the coolant is at least partially in a vapor state when it reaches the fans 436a-436c.

In other embodiments, liquid enhanced air cooling (LEAC) may be used when high-power components need to be liquid cooled to meet junction temperature requirements, while the rest of the components may still be air cooled.

In embodiments, when high-power components are cooled by a two-phase (liquid and gas) coolant, vapors may be generated by absorbing latent heat of vaporization. As the liquid turns into vapor, due to density differences, the coolant generates additional pressure. This generated pressure may be proportional to the amount of vapor generated and hence proportional to the heat load. In embodiments, pump 404 may ensure that the coolant flows in the proper direction 402a. When the liquid and gas coolant passes through the rotor 216, the pressure of the mixture may be reduced and may help heat exchanger 410 performance. The coolant moving through the fans may increase the coolant pressure drop. As discussed above, similar to expansion valve in a refrigerator unit, due to the additional pressure drop, gas velocity may decrease and may help condense the refrigerant by lowering operating pressure of the coolant going into the heat exchanger. This may increase the thermal performance of the overall LEAC loop. In embodiments, the rotor 216 may act as an expansion valve and at the same time generate some work on the fan side.

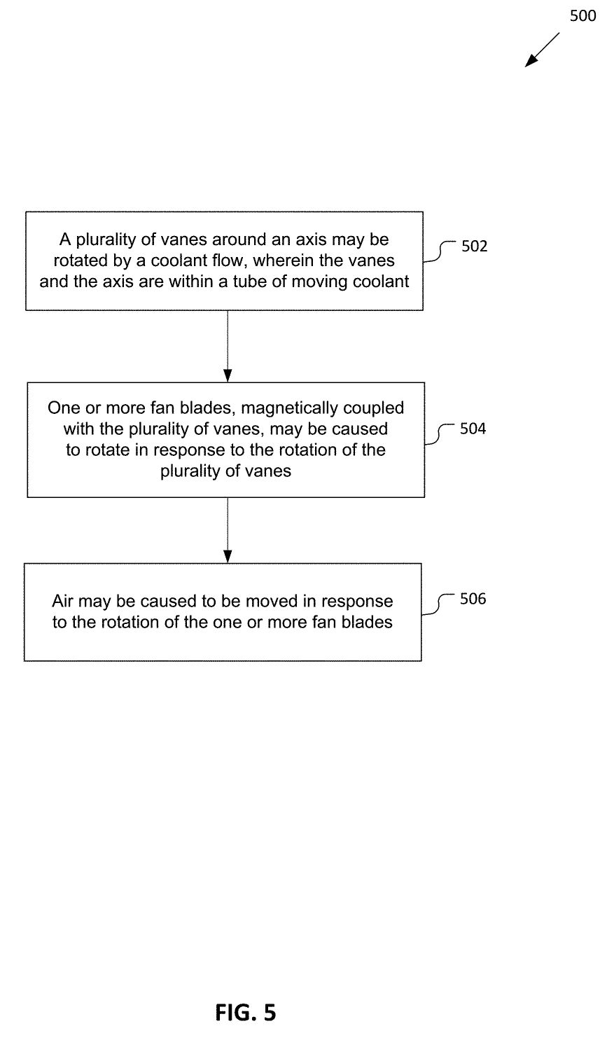

FIG. 5 illustrates a block diagram of a process for implementing cooling using coolant-driven fans, in accordance with some embodiments. The fans 106 of FIG. 1, the fan of diagram 200 of FIG. 2, the fans 338a-338c of FIG. 3, or the fans 436a-436c of FIG. 4 may perform one or more processes, such as the process 500, described herein.

At block 502, a plurality of vanes around an axis may be rotated by a coolant flow, wherein the vanes and the axis are within a tube of moving coolant. In embodiments, the vanes may be similar to vanes 216a of FIG. 2, and the axis may be similar to hub 216b of rotor 216 of FIG. 2. In embodiments, the resulting rotation may be similar to rotation 216c of FIG. 2.

At block 504, one or more fan blades, magnetically coupled with the plurality of vanes, may be caused to rotate in response to the rotation of the plurality of vanes. In embodiments, the plurality of vanes may be the vanes 216a, which may be a magnet, such as a permanent magnet. In embodiments, the coolant tube surrounding the vanes, such as coolant tube 202 of FIG. 2, may allow magnetic flux lines to penetrate the tube walls and interact with, for example, fan blades such as fan blade 218 of FIG. 2.

At block 506, air may be caused to be moved in response to the rotation of the one or more fan blades.

Various operations are described as multiple discrete operations in turn, in a manner that is most helpful in understanding the claimed subject matter. However, the order of description should not be construed as to imply that these operations are necessarily order dependent.

### EXAMPLES

Example 1 may be a cooling apparatus, comprising: one or more fan blades; a tube to carry coolant flowing within the tube; the tube proximate to the one or more fan blades; and a mechanism within the tube, the mechanism kinetically coupled to the one or more fan blades, wherein the flow of the coolant is to cause the mechanism to move the one or more fan blades to create airflow.

Example 2 may include the subject matter of 1, wherein the mechanism comprises: a plurality of vanes rotatable around an axis, wherein the vanes are to rotate around the axis when the coolant flows within the tube; and at least one of the plurality of vanes is magnetically coupled to the one or more fan blades to cause the one or more fan blades to move when the coolant flows through the tube.

Example 3 may include the subject matter of Examples 1-2, wherein the tube is made of a tube material that allows magnetic flux lines to pass through the tube material.

Example 4 may include the subject matter of Example 3, wherein the tube material is aluminum or stainless steel.

Example 5 may include the subject matter of Example 2, wherein the axis is parallel to the coolant flow in the tube.

Example 6 may include the subject matter of Examples 1-2, wherein the coolant is liquid, vapor, or both.

Example 7 may be a method for cooling, the method comprising: rotating a plurality of vanes around an axis, wherein the vanes and the axis are within a tube of moving coolant; magnetically transferring rotational energy of the plurality of vanes to one or more fan blades; and rotating, based on the transferred rotational energy, the one or more fan blades to cause air to be moved.

Example 8 may include the subject matter of Example 7, wherein rotating a plurality of vanes around an axis comprises rotating the plurality of vanes around an axis within a tube made of a tube material that allows magnetic flux lines to pass through the tube material.

Example 9 may include the subject matter of Example 8, wherein the tube material is aluminum or stainless steel.

Example 10 may include the subject matter of Examples 7-8, wherein rotating a plurality of vanes around an axis comprises rotating the plurality of vanes around an axis within a tube of moving liquid, vapor, or both.

Example 11 may include the subject matter of Example 10, wherein the coolant flowing through the rotating plurality of vanes around the axis within the tube is to cause the coolant to drop in pressure.

Example 12 may include the subject matter of Example 11, wherein the drop in coolant pressure is further to condense the coolant.

Example 13 may be a system for cooling, the system comprising: a cooling apparatus that includes: one or more fan blades; a tube to carry coolant flowing within the tube; the tube proximate to the one or more fan blades; a mechanism within the tube, the mechanism kinetically coupled to the one or more fan blades, wherein the flow of the coolant is to cause the mechanism to move the one or more fan blades to create airflow; a plurality of vanes rotatable around an axis, wherein the vanes are to rotate around the axis when the coolant flows within the tube; and at least one of the plurality of vanes is magnetically coupled to the one or more fan blades to cause the one or more fan blades to move when the coolant flows through the tube; a cold plate proximate to the tube, the cold plate thermally coupled to the coolant flowing within the tube to add heat to the coolant and reduce a temperature of the cold plate; and a heat exchanger connected to the tube, the heat exchanger thermally coupled to the coolant flowing within the tube to remove heat from the coolant.

Example 14 may include the subject matter of Example 13, further comprising a pump connected to the tube, the pump to cause coolant to flow through the tube.

Example 15 may include the subject matter of Examples 13-14, wherein the tube material is aluminum or stainless steel.

Example 16 may include the subject matter of Examples 13-14, wherein the axis is parallel to the coolant flow in the tube.

Example 17 may include the subject matter of Example 16, wherein the coolant flowing through the rotating plurality of vanes around the axis within the tube is to cause the coolant to drop in pressure.

Example 18 may include the subject matter of Example 17, wherein the drop in coolant pressure is further to condense the coolant.

Example 19 may include the subject matter of Example 17, wherein the drop in coolant pressure is to lower pressure of the coolant entering the heat exchanger.

Example 20 may include the subject matter of Example 17, wherein the drop in coolant pressure is to change a state of the coolant from a vapor state to a liquid state.

Example 21 may be a cooling apparatus, comprising: means for rotating a plurality of vanes around an axis, wherein the vanes and the axis are within a tube of moving coolant; means for magnetically transferring rotational energy of the plurality of vanes to one or more fan blades; and means for rotating, based on the transferred rotational energy, the one or more fan blades to cause air to be moved.

Example 22 may include the subject matter of Example 21, wherein rotating a plurality of vanes around an axis further comprises means for rotating the plurality of vanes around an axis within a tube made of a tube material that allows magnetic flux lines to pass through the tube material.

Example 23 may include the subject matter of Examples 21-22, wherein the tube material is aluminum or stainless steel.

Example 24 may include the subject matter of Examples 21-22, wherein rotating a plurality of vanes around an axis comprises rotating the plurality of vanes around an axis within a tube of moving liquid, vapor, or both.

Example 25 may include the subject matter of Example 24, wherein the coolant flowing through the rotating plurality of vanes around the axis within the tube is to cause the coolant to drop in pressure.

Example 26 may include the subject matter of Example 25, wherein the drop in coolant pressure is further to condense the coolant.

Example 27 may include the subject matter of Example 25, wherein the drop in coolant pressure is to change a state of the coolant from a vapor state to a liquid state.

The foregoing description of one or more implementations provides illustration and description, but is not intended to be exhaustive or to limit the scope of the embodiments to the precise form disclosed or claimed herein. Modifications and variations are possible in light of the above teachings or may be acquired from practice of various implementations of the various embodiments. Future improvements, enhancements, or changes to particular components, methods, or means described in the various embodiments are contemplated to be within the scope of the claims and embodiments described herein, as would readily be understood by a person having ordinary skill in the art.

What is claimed is:

1. A cooling apparatus, comprising:
one or more fan blades;
a tube to carry coolant flowing within the tube; the tube proximate to the one or more fan blades; and
a mechanism within the tube, the mechanism kinetically coupled to the one or more fan blades, wherein the flow of the coolant is to cause the mechanism to move the one or more fan blades to create airflow.

2. The cooling apparatus of claim 1, wherein the mechanism comprises:
a plurality of vanes rotatable around an axis, wherein the vanes are to rotate around the axis when the coolant flows within the tube; and
at least one of the plurality of vanes is magnetically coupled to the one or more fan blades to cause the one or more fan blades to move when the coolant flows through the tube.

3. The cooling apparatus of claim 1, wherein the tube is made of a tube material that allows magnetic flux lines to pass through the tube material.

4. The cooling apparatus of claim 3, wherein the tube material is aluminum or stainless steel.

5. The cooling apparatus of claim 2, wherein the axis is parallel to the coolant flow in the tube.

6. The cooling apparatus of claim 1, wherein the coolant is liquid, vapor, or both.

7. A method for cooling, the method comprising:
rotating a plurality of vanes around an axis, wherein the vanes and the axis are within a tube of moving coolant;
magnetically transferring rotational energy of the plurality of vanes to one or more fan blades; and
rotating, based on the transferred rotational energy, the one or more fan blades to cause air to be moved.

8. The method of claim 7, wherein rotating a plurality of vanes around an axis comprises rotating the plurality of vanes around an axis within a tube made of a tube material that allows magnetic flux lines to pass through the tube material.

9. The method of claim 8, wherein the tube material is aluminum or stainless steel.

10. The method of claim 7, wherein rotating a plurality of vanes around an axis comprises rotating the plurality of vanes around an axis within a tube of moving liquid, vapor, or both.

11. The method of claim 10, wherein the coolant flowing through the rotating plurality of vanes around the axis within the tube is to cause the coolant to drop in pressure.

12. The method of claim 11, wherein the drop in coolant pressure is further to condense the coolant.

13. A system for cooling, the system comprising:
a cooling apparatus that includes:
one or more fan blades;
a tube to carry coolant flowing within the tube; the tube proximate to the one or more fan blades;
a mechanism within the tube, the mechanism kinetically coupled to the one or more fan blades, wherein the flow of the coolant is to cause the mechanism to move the one or more fan blades to create airflow;
a plurality of vanes rotatable around an axis, wherein the vanes are to rotate around the axis when the coolant flows within the tube; and
at least one of the plurality of vanes is magnetically coupled to the one or more fan blades to cause the one or more fan blades to move when the coolant flows through the tube;
a cold plate proximate to the tube, the cold plate thermally coupled to the coolant flowing within the tube to add heat to the coolant and reduce a temperature of the cold plate; and
a heat exchanger connected to the tube, the heat exchanger thermally coupled to the coolant flowing within the tube to remove heat from the coolant.

14. The system of claim 13, further comprising a pump connected to the tube, the pump to cause coolant to flow through the tube.

15. The system of claim 13, wherein the tube material is aluminum or stainless steel.

16. The system of claim 13, wherein the axis is parallel to the coolant flow in the tube.

17. The system of claim 16, wherein the coolant flowing through the rotating plurality of vanes around the axis within the tube is to cause the coolant to drop in pressure.

18. The system of claim 17, wherein the drop in coolant pressure is further to condense the coolant.

19. The system of claim 17, wherein the drop in coolant pressure is to lower pressure of the coolant entering the heat exchanger.

20. The system of claim 17, wherein the drop in coolant pressure is to change a state of the coolant from a vapor state to a liquid state.

21. A cooling apparatus, comprising:
means for rotating a plurality of vanes around an axis, wherein the vanes and the axis are within a tube of moving coolant;
means for magnetically transferring rotational energy of the plurality of vanes to one or more fan blades; and
means for rotating, based on the transferred rotational energy, the one or more fan blades to cause air to be moved.

22. The apparatus of claim 21, wherein rotating a plurality of vanes around an axis further comprises means for rotating the plurality of vanes around an axis within a tube made of a tube material that allows magnetic flux lines to pass through the tube material.

23. The apparatus of claim 21, wherein the tube material is aluminum or stainless steel.

24. The apparatus of claim 21, wherein rotating a plurality of vanes around an axis comprises rotating the plurality of vanes around an axis within a tube of moving liquid, vapor, or both.

25. The apparatus of claim 24, wherein the coolant flowing through the rotating plurality of vanes around the axis within the tube is to cause the coolant to drop in pressure.
